(19) United States
(12) Patent Application Publication
(10) Pub. No.: US 2022/0069803 A1
(43) Pub. Date: Mar. 3, 2022

(54) ELASTIC WAVE DEVICE, SPLITTER, AND COMMUNICATION APPARATUS

(71) Applicant: KYOCERA Corporation, Kyoto-shi, Kyoto (JP)

(72) Inventor: Soichiro NOZOE, Soraku-gun, Kyoto (JP)

(21) Appl. No.: 17/414,778

(22) PCT Filed: Dec. 20, 2019
(86) PCT No.: PCT/JP2019/050045

§ 371 Date: Jun. 16, 2021

(30) Foreign Application Priority Data
Dec. 21, 2018 (JP) 2018-239125

(51) Int. Cl. H03H 9/56; H03H 9/17; H03H 9/13; H01P 5/16

(52) U.S. Cl. CPC H03H 9/568; H01P 5/16; H03H 9/13; H03H 9/17

(57) ABSTRACT

An elastic wave device includes a substrate, a multilayer film located on the substrate, an LT layer located on the multilayer film and made of a single crystal of LiTaO₃, and an IDT electrode located on the LT layer. The LT layer has a thickness of 0.3λ or less, where λ is twice a pitch of electrode fingers of the IDT electrode. The LT layer has Euler angles of (0°±10°, −25° or more and 15° or less, 0° or more and 360° or less).

### TECHNICAL FIELD

The present disclosure relates to an elastic wave device that uses an elastic wave, a splitter including the elastic wave device, and a communication apparatus.

### BACKGROUND ART

There is known an elastic wave device that applies a voltage to an interdigital transducer (IDT) electrode on a piezoelectric body to generate an elastic wave that propagates through the piezoelectric body. The IDT electrode includes a pair of comb-teeth electrodes. The pair of comb-teeth electrodes each have a plurality of electrode fingers (corresponding to comb teeth) and are disposed so as to interdigitate with each other. In the elastic wave device, a standing wave of an elastic wave having a wavelength that is twice the pitch of the electrode fingers is formed, and the frequency of this standing wave serves as a resonant frequency. Thus, a resonant point of the elastic wave device is defined by the pitch of the electrode fingers.

As an elastic wave device, there has recently been proposed a device including a substrate, an acoustic reflection layer located on the substrate, a piezoelectric layer located on the acoustic reflection layer, and an IDT electrode located on the piezoelectric layer. The acoustic reflection layer is formed of low acoustic impedance layers and high acoustic impedance layers that are alternately stacked. With this configuration, a Lamb wave can be used as an elastic wave, and a period of electrode fingers of about 3 μm having resonance at 5 GHz can be achieved.

### SUMMARY OF INVENTION

### Technical Problem

It is desired to provide an elastic wave device, a splitter, and a communication apparatus that are capable of achieving resonance at a relatively high frequency with respect to the pitch of electrode fingers.

### Solution to Problem

An elastic wave device according to an aspect of the present disclosure includes an LN layer made of a single crystal of LiNbO₃, and an IDT electrode located on the LN layer. The LN layer has a thickness of 0.3λ or less, where is twice a pitch of electrode fingers of the IDT electrode. The LT layer has Euler angles (ϕ, θ, ψ) of (0°±10°, −25° or more and 15° or less, 0° or more and 360° or less).

A splitter according to an aspect of the present disclosure includes an antenna terminal, a transmission filter configured to filter a signal that is to be output to the antenna terminal, and a reception filter configured to filter a signal received from the antenna terminal. At least one of the transmission filter or the reception filter includes the above elastic wave device.

A communication apparatus according to an aspect of the present disclosure includes an antenna, the above splitter comprising the antenna terminal connected to the antenna, and an IC connected to the transmission filter and the reception filter, the IC being connected on an opposite side from the antenna terminal in a signal path.

### Advantageous Effects of Invention

According to the above-described configuration, it is possible to achieve resonance at a relatively high frequency with respect to the pitch of electrode fingers.

### BRIEF DESCRIPTION OF DRAWINGS

FIG. 1 is a plan view of an elastic wave device according to an embodiment.

FIG. 2 is a sectional view taken along line II-II of the elastic wave device in FIG. 1.

FIG. 3(a), FIG. 3(b), and FIG. 3(c) are graphs illustrating impedance characteristics, phase characteristics, and a difference between a resonant frequency and an anti-resonant frequency of a resonator according to the embodiment.

FIG. 4(a), FIG. 4(b), FIG. 4(c), and FIG. 4(d) are graphs illustrating impedance characteristics, phase characteristics, a resonant frequency, and a difference between a resonant frequency and an anti-resonant frequency and a maximum phase value of the resonator according to the embodiment.

FIG. 5(a), FIG. 5(b), and FIG. 5(c) are plan views illustrating disposition examples of a plurality of resonators.

FIG. 6 includes graphs illustrating characteristics of resonators according to Comparative Examples.

FIG. 7(a), FIG. 7(b), and FIG. 7(c) are graphs corresponding to FIG. 3, with the thickness of an LN layer being varied.

FIG. 8(a) and FIG. 8(b) are graphs illustrating impedance characteristics and phase characteristics of the resonator according to the embodiment.

FIG. 9(a) and FIG. 9(b) are graphs illustrating impedance characteristics and phase characteristics of the resonator according to the embodiment.

FIG. 10(a) and FIG. 10(b) are graphs illustrating impedance characteristics and phase characteristics of the resonator according to the embodiment.

FIG. 11 is a circuit diagram schematically illustrating a configuration of a splitter as an application example of the elastic wave device in FIG. 1.

FIG. 12 is a circuit diagram schematically illustrating a configuration of a communication apparatus as an application example of the elastic wave device in FIG. 1.

FIG. 13 is a sectional view illustrating a modification of the elastic wave device illustrated in FIG. 2.

FIG. 14(a) and FIG. 14(b) are graphs illustrating impedance characteristics and phase characteristics of the elastic wave device illustrated in FIG. 13.

FIG. 15(a), FIG. 15(b), and FIG. 15(c) are graphs illustrating a resonant frequency, a difference between a resonant frequency and an anti-resonant frequency, and a maximum phase value of the elastic wave device illustrated in FIG. 13.

### DESCRIPTION OF EMBODIMENTS

Hereinafter, an embodiment according to the present disclosure will be described with reference to the drawings. The drawings used in the following description are schematic, and dimensional ratios and the like in the drawings do not necessarily coincide with actual dimensional ratios.

In an elastic wave device according to the present disclosure, either direction may be an upward direction or a downward direction. Hereinafter, for the sake of convenience, an orthogonal coordinate system composed of a D1 axis, a D2 axis, and a D3 axis is defined, and a term such as an upper surface or a lower surface may be used under the assumption that the positive side of the D3 axis corresponds to an upward direction. In addition, a plan view or a perspective plan view refers to a view in a D3-axis direction unless otherwise specified. The D1 axis is defined to be parallel to a propagation direction of an elastic wave that propagates along an upper surface of an LN layer described below. The D2 axis is defined to be parallel to the upper surface of the LN layer and to be orthogonal to the D1 axis. The D3 axis is defined to be orthogonal to the upper surface of the LN layer.

(Overall Configuration of Elastic Wave Device)

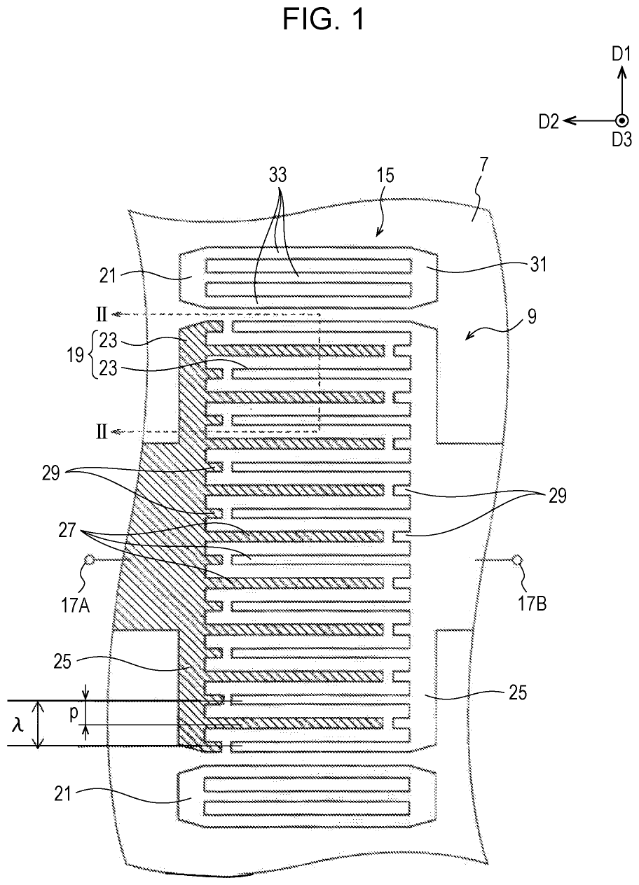

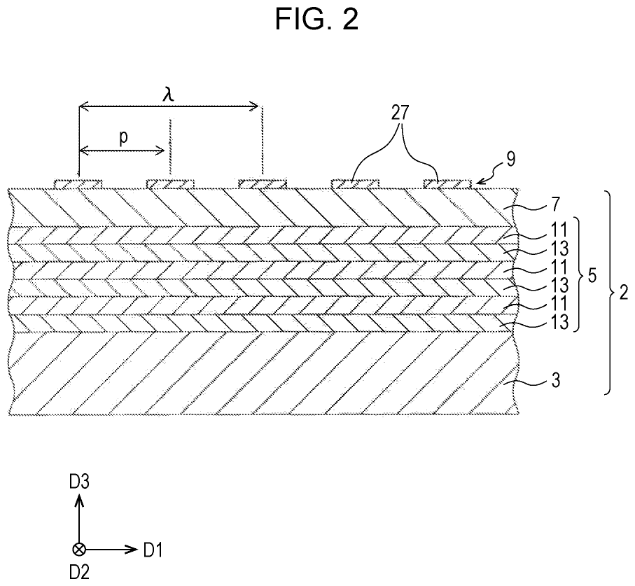

FIG. 1 is a plan view illustrating a configuration of a main part of an elastic wave device 1. FIG. 2 is a sectional view taken along line II-II in FIG. 1.

The elastic wave device 1 includes, for example, a substrate 3 (FIG. 2), a multilayer film 5 (FIG. 2) located on the substrate 3, an LN layer 7 located on the multilayer film 5, and a conductive layer 9 located on the LN layer 7. Each layer has, for example, a substantially uniform thickness. A combination of the substrate 3, the multilayer film 5, and the LN layer 7 may be referred to as an affixed substrate 2 (FIG. 2).

In the elastic wave device 1, a voltage applied to the conductive layer 9 excites an elastic wave that propagates through the LN layer 7. The elastic wave device 1 constitutes, for example, a resonator and/or a filter that uses this elastic wave. For example, the multilayer film 5 contributes to reflecting the elastic wave and confining energy of the elastic wave in the LN layer 7. For example, the substrate 3 contributes to increasing the strength of the multilayer film 5 and the LN layer 7.

(Schematic Configuration of Affixed Substrate)

The substrate 3 does not have a direct influence on the electrical characteristics of the elastic wave device 1, as is understood from the description given below. Thus, the material and dimensions of the substrate 3 may be appropriately set. The material of the substrate 3 is, for example, an insulating material. The insulating material is, for example, a resin or a ceramic. The substrate 3 may be made of a material having a lower thermal expansion coefficient than the LN layer 7 or the like. In this case, for example, a possibility that the frequency characteristics of the elastic wave device 1 are changed by a temperature change can be reduced. Examples of such a material include a semiconductor such as silicon, a single crystal such as sapphire, and a ceramic such as sintered aluminum oxide. The substrate 3 may be formed of a plurality of stacked layers made of materials different from each other. The substrate 3 is thicker than the LN layer 7, for example.

The multilayer film 5 is formed of low acoustic velocity layers 11 and high acoustic velocity layers 13 that are alternately stacked. The low acoustic velocity layers 11 are made of, for example, a material having a lower acoustic velocity than the LN layer 7, such as silicon dioxide (SiO₂). The high acoustic velocity layers 13 are made of, for example, a material having a higher acoustic velocity than the LN layer 7, such as tantalum pentoxide (Ta₂O₅) or hafnium oxide (HfO₃). The high acoustic velocity layers 13 have a higher acoustic impedance than the low acoustic velocity layers 11. Thus, the reflectivity for an elastic wave is relatively high at the interfaces between these layers. As a result, for example, leakage of an elastic wave that propagates through the LN layer 7 is reduced.

The number of stacked layers in the multilayer film 5 may be appropriately set. For example, the total number of low acoustic velocity layers 11 and high acoustic velocity layers 13 stacked in the multilayer film 5 may be three or more and twelve or less. However, the multilayer film 5 may be formed of two layers in total including one low acoustic velocity layer 11 and one high acoustic velocity layer 13. The total number of stacked layers in the multilayer film 5 may be an even number or an odd number, but the layer that is in contact with the LN layer 7 is the low acoustic velocity layer 11. The layer that is in contact with the substrate 3 may be the low acoustic velocity layer 11 or the high acoustic velocity layer 13. A supplementary layer may be inserted between the individual layers for the purpose of close contact or diffusion inhibition. In this case, no problem arises when the layer is thin enough not to affect the characteristics (about 0.01λ or less, where a wavelength λ described below is a reference).

The LN layer 7 is made of a single crystal of lithium niobate (LiNbO₃, LN). The LN layer 7 has cut angles of, for example, (0°±10°, −25° or more and 15° or less, 0° or more and 360° or less) in Euler angles (ϕ, θ, ψ). The LN layer 7 has a relatively small thickness, for example, a thickness of 0.3λ or less, where h is a reference. As a result of setting the cut angles and the thickness of the LN layer 7 in the above-described manner, it is possible to use, as an elastic wave, a wave of an oscillation mode close to a slab mode. In other words, because an A1-mode Lamb wave can be used as an elastic wave, resonance at a high frequency can be achieved even when the distance between electrode fingers 27 of an IDT electrode 19 described below is relatively large.

(Schematic Configuration of Conductive Layer)

The conductive layer 9 is made of, for example, a metal. The metal may be of an appropriate type, and is, for example, aluminum (Al) or an alloy containing Al as a main component (Al alloy). The Al alloy is, for example, an aluminum-copper (Cu) alloy. The conductive layer 9 may be formed of a plurality of metal layers. For example, a relatively thin layer made of titanium (Ti) may be provided between the Al or Al alloy and the LN layer 7 to enhance the bonding therebetween.

In the example illustrated in FIG. 1, the conductive layer 9 is formed to constitute a resonator 15. The resonator 15 is configured as a so-called one-port elastic wave resonator. In response to input of an electric signal having a predetermined frequency from one of terminals 17A and 17B, which are conceptually and schematically illustrated, the resonator 15 is capable of generating resonance and outputting a signal caused by the resonance from the other of the terminals 17A and 17B.

The conductive layer 9 (the resonator 15) includes, for example, the IDT electrode 19 and a pair of reflectors 21 located on both sides of the IDT electrode 19.

The IDT electrode 19 includes a pair of comb-teeth electrodes 23. To improve visibility, one of the comb-teeth electrodes 23 is hatched. Each comb-teeth electrode 23 includes, for example, a busbar 25, a plurality of electrode fingers 27 extending from the busbar 25 in parallel to each other, and dummy electrodes 29 protruding from the busbar 25 between the plurality of electrode fingers 27. The pair of comb-teeth electrodes 23 are disposed such that the plurality of electrode fingers 27 interdigitate (intersect) with each other.

The busbar 25 has, for example, an elongated shape linearly extending in an elastic wave propagation direction (a repetitive arrangement direction of the electrode fingers 27, a D1-axis direction in this example) with a substantially uniform width. The pair of busbars 25 face each other in a direction orthogonal to the elastic wave propagation direction (a D2-axis direction). The busbar 25 may have an ununiform width or may be inclined with respect to the elastic wave propagation direction.

Each electrode finger 27 has, for example, an elongated shape linearly extending in the direction orthogonal to the elastic wave propagation direction (the D2-axis direction) with a substantially uniform width. In each comb-teeth electrode 23, the plurality of electrode fingers 27 are arranged in the elastic wave propagation direction. The plurality of electrode fingers 27 of one of the comb-teeth electrodes 23 and the plurality of electrode fingers 27 of the other comb-teeth electrode 23 are alternately arranged in principle.

A pitch p of the plurality of electrode fingers 27 (for example, the distance between centers of two electrode fingers 27 adjacent to each other) is basically constant in the IDT electrode 19. A part of the IDT electrode 19 may have a narrow pitch portion in which the pitch p is smaller than that in most of the other portions or a wide pitch portion in which the pitch p is larger than that in most of the other portions.

In the following description, the pitch p refers to a pitch in a portion (the majority of the plurality of electrode fingers 27) other than an exceptional portion such as the foregoing narrow pitch portion or wide pitch portion unless otherwise specified. In a case where the pitch varies also in the majority of the plurality of electrode fingers 27 other than the exceptional portion, an average value of the pitches of the majority of the plurality of electrode fingers 27 may be used as the value of the pitch p. A value that is twice the pitch p is assumed to be a wavelength λ.

The number of electrode fingers 27 may be appropriately set in accordance with electrical characteristics or the like required for the resonator 15. FIG. 2 is a schematic diagram, and thus the number of electrode fingers 27 illustrated therein is small. The same applies to strip electrodes 33 of the reflectors 21 described below.

The lengths and widths of the plurality of electrode fingers 27 may be appropriately set in accordance with required electrical characteristics or the like.

The dummy electrodes 29 protrude, for example, in the direction orthogonal to the elastic wave propagation direction with a substantially uniform width. The plurality of dummy electrodes 29 are arranged at a pitch equivalent to that of the plurality of electrode fingers 27. Tip ends of the dummy electrodes 29 of one of the comb-teeth electrodes 23 face tip ends of the electrode fingers 27 of the other comb-teeth electrode 23 with gaps therebetween. The IDT electrode 19 does not necessarily include the dummy electrodes 29.

The pair of reflectors 21 are located on both sides of the plurality of IDT electrodes 19 in the elastic wave propagation direction. The reflector 21 includes a pair of busbars 31 facing each other, and a plurality of strip electrodes 33 extending between the pair of busbars 31.

Although not particularly illustrated, the upper surface of the LN layer 7 may be covered with a protective film made of SiO₂, Si₃N₄, or the like from above the conductive layer 9. The protective film may be a multilayer body of a plurality of layers made of these materials. The protective film may be a film for simply suppressing corrosion of the conductive layer 9 or may be a film that contributes to temperature compensation. In a case where the protective film is provided, for example, to improve the reflection coefficient of an elastic wave, a supplementary film made of an insulator or a metal may be provided on the upper surfaces or lower surfaces of the IDT electrode 19 and the reflectors 21.

The configuration illustrated in FIG. 1 and FIG. 2 may be appropriately packaged. The package may be, for example, a package in which the illustrated configuration is mounted on a substrate that is not illustrated such that the upper surface of the LN layer 7 faces the substrate with a gap interposed therebetween, and resin sealing is applied thereto, or may be a wafer level package in which a box-shaped cover is provided over the LN layer 7.

(Use of Slab Mode)

The LN layer 7 is relatively thin and has Euler angles (ϕ, θ, ψ) of (0°±10°, −25° to 15°, 0° to 360°). Thus, a slab-mode elastic wave can be used. The propagation velocity (acoustic velocity) of a slab-mode elastic wave is higher than the propagation velocity of a typical surface acoustic wave (SAW). For example, the propagation velocity of a typical SAW is 3000 to 4000 m/s, whereas the propagation velocity of a slab-mode elastic wave is 10000 m/s or more. Thus, it is possible to achieve resonance in a higher frequency region than in the related art with the pitch p equivalent to the pitch in the related art. For example, a resonant frequency (fr) of 5 GHz or more can be achieved with the pitch p of 1 μm or more.

(Settings of Material and Thickness of Each Layer)

The inventor of the present application conducted simulation calculations on the frequency characteristics of the elastic wave device 1 while variously changing the material and thickness of the multilayer film 5, the Euler angles, material, and thickness of the piezoelectric layer (the LN layer 7 in the present embodiment), and the thickness of the conductive layer 9. The inventor found a condition that enables resonance in a relatively high frequency region (for example, 5 GHz or more) to be achieved by using a slab-mode elastic wave. The details are as follows.

(Propagation Angle of LN Layer 7)

First, a simulation was conducted by variously changing the cut angles and the propagation angle of the piezoelectric layer (LN layer 7). As a result, it was found that resonance in a relatively high frequency region was achievable using a slab-mode elastic wave by setting ϕ and θ related to the cut angles to 0°±10° and −25° to 15°, respectively, in the Euler angles (ϕ, θ, ψ). Furthermore, it was found that there was no limitation on ψ related to the propagation angle in a case where the LN layer 7 was 0.3λ or less and ϕ and θ were within this range.

First, a simulation was conducted by changing the Euler angles of the LN layer 7, and (0, 0, 0) was found as the Euler angles of the LN layer 7 with which resonance in a relatively high frequency region was achievable and no spurious was present near fr and an anti-resonant frequency (fa). The thickness of the LN layer 7 is 0.1875λ, the thickness of the low acoustic velocity layer 11 is 0.09λ, the thickness of the high acoustic velocity layer 13 is 0.07λ, the thickness of the conductive layer 9 is 0.06λ, the pitch p is 1 μm, and a duty is 0.5.

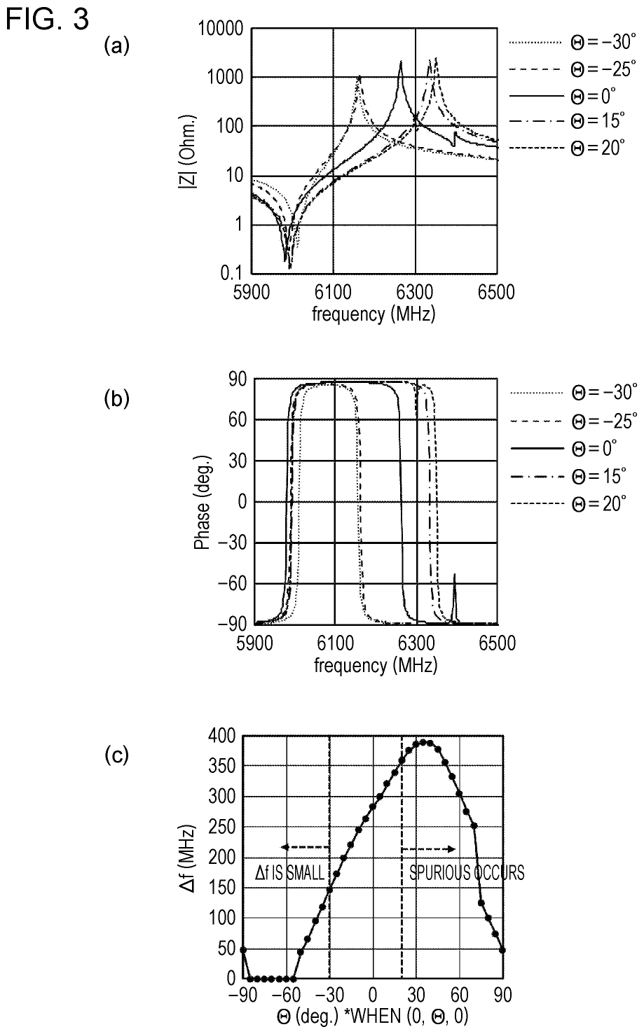

Next, a case where ϕ and θ were changed from the Euler angles (0, 0, 0) will be discussed. As a result, it was found that the resonance waveform was deformed when was changed beyond ±10°. FIG. 3(a) to FIG. 3(c) illustrate measurement results of frequency characteristics when θ was changed. FIG. 3(a) illustrates impedance characteristics, FIG. 3(b) illustrates phase characteristics, and FIG. 3(c) is a graph illustrating a state of change in a difference (Δf) between fr and fa when θ was changed. In FIG. 3(a) and FIG. 3(b), the horizontal axis represents frequency, and the vertical axis represents the absolute value of impedance in FIG. 3(a) and phase in FIG. 3(b). In FIG. 3(c), the horizontal axis represents θ, and the vertical axis represents Δf.

As is apparent from the figure, when θ is smaller than −25°, Δf is equivalent to or smaller than that in a case where a lithium tantalate (LT) crystal is used, although an LN crystal is used. In addition, it was found that spurious occurred near fr and fa when θ was greater than 15°. From the above, it is possible to obtain an elastic wave element having a large Δf and a reduced influence of spurious, when θ is −25° to 15°.

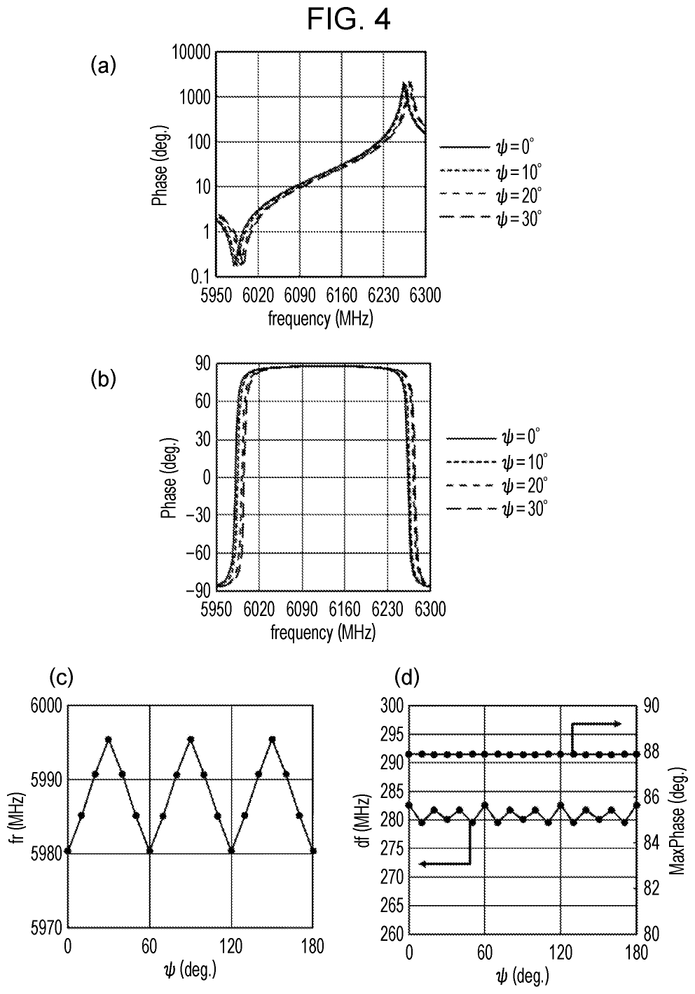

Next, a simulation was conducted by changing ψ. The results are illustrated in FIG. 4. FIG. 4(a) illustrates impedance characteristics, FIG. 4(b) illustrates phase characteristics, FIG. 4(c) illustrates fr, and FIG. 4(d) illustrates Δf and a maximum phase value (MaxPhase) between fr and fa.

As is apparent from the figure, even when ψ was changed, no spurious occurred, and MaxPhase did not change. That is, an increase in loss caused by ψ was not observed. It was found that although Δf periodically varied, the center value of the variation did not change, the variation width had a very small value of less than 5 MHz, and the absolute value of Δf maintained a value sufficiently greater than LT. Furthermore, when fr was focused on, fr varied in a period of 60°, took a maximum value when 30°+60°×n1 (n1 is a natural number from 0 to 5), took a minimum value when 0°+60°×n2 (n2 is a natural number from 0 to 5), and the difference therebetween was about 15 MHz.

From the above, a plurality of resonators 15, each of which is the one illustrated in FIG. 1, may be provided, and the propagation angles thereof (repetitive arrangement directions of electrode fingers) may be different from each other. For example, when a filter is formed by connecting a plurality of resonators 15 in a ladder shape, the propagation angles of series resonators may be different from the propagation angles of parallel resonators. Specifically, the propagation angle of each series resonator may be any one of 15° to 45°, 75° to 105°, 135° to 165°, 195° to 225°, 255° to 285°, and 315° to 345°; whereas the propagation angle of each parallel resonator may be −15° (345°) to 15°, 45° to 75°, 105° to 135°, 165° to 195°, 225° to 255°, or 285° to 315°. Note that the angle range of the series resonator includes an upper limit value and a lower limit value, and the angle range of the parallel resonator does not include an upper limit value and a lower limit value.

More preferably, the propagation angle of the series resonator may be 20°+60°×n1 or more and 40°+60°×n1 or less, and the propagation angle of the parallel resonator may be −10°+60°×n2 or more and 10°+60°×n2 or less. Hereinafter, a propagation angle may be represented by ψ.

With this configuration, fr can be changed by a difference in propagation angle in addition to control of fr using the pitch p of the electrode fingers, and thus designing is facilitated. For example, fr can be further moved to the high frequency side without reducing the pitch p. The thickness of the LN layer 7 and the thickness of each layer in the multilayer film 5 are optimized by the pitch p of the electrode fingers 27. Even when there are a plurality of resonators 15 having different fr, the pitches p of the resonators 15 can be made close to each other. Thus, a high-performance elastic wave device can be provided.

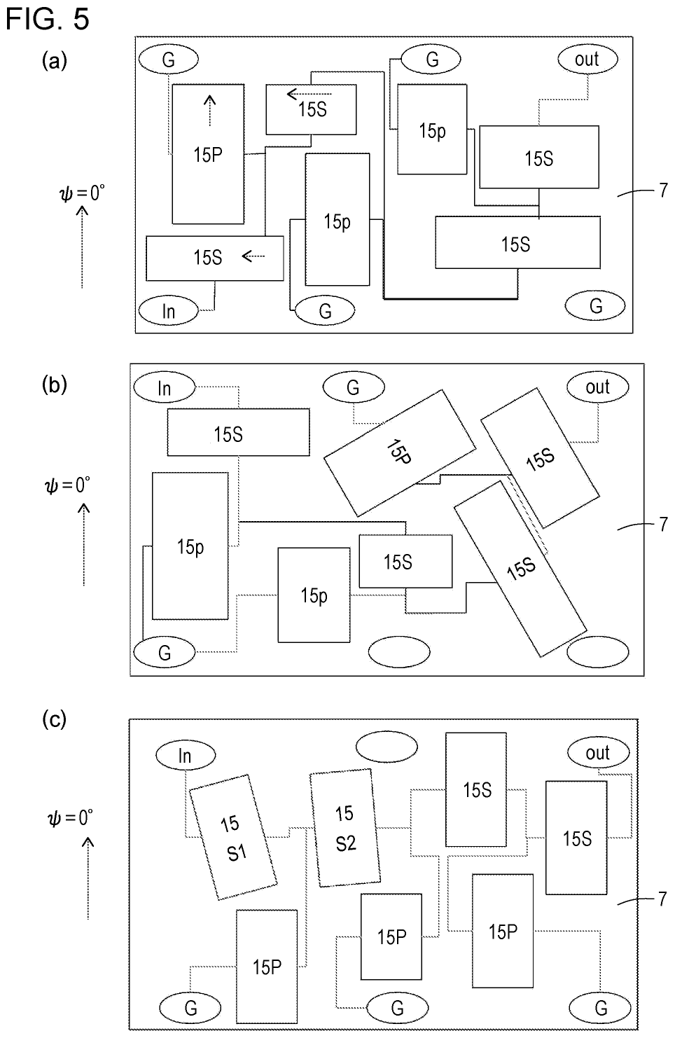

Specifically, as illustrated in FIG. 5(a), series resonators 15S (first resonators) may be disposed such that ψ is 90°, and parallel resonators 15P (second resonators) may be disposed such that ψ is 0°. That is, the series resonators 15S and the parallel resonators 15P are different in orientation by 90°. In this case, the degree of freedom in layout of the plurality of resonators 15 constituting the filter can be increased.

Furthermore, as illustrated in FIG. 5(b), the series resonators 15S may be disposed such that ψ is 30° or 90°, and the parallel resonators 15P may be disposed such that ψ is 0° or 60°. In this case, the degree of freedom in layout is further increased.

In the above-described examples, the propagation angle is different between the series resonators 15S and the parallel resonators 15P. Alternatively, the propagation angle may be different between the series resonators or between the parallel resonators. In a ladder filter, fr may be different between series resonators or between parallel resonators for the purpose of improving the shoulder characteristic of the filter or adjusting the out-of-band attenuation characteristic. Propagation angles may be used for this adjustment.

FIG. 5(c) illustrates a case where the propagation angle (ψ) is different between the series resonators. The series resonators 15S may include a first series resonator 15S1 (first resonator) and a second series resonator 15S2 (second resonator). With this configuration, it is possible to obtain resonators having the same pitch and different fr. Thus, for example, it is possible to suppress a decrease in power handling capability resulting from a decrease in pitch and concentration of power in a specific resonator.

As illustrated in FIG. 5(a) to FIG. 5(c), when the resonators are disposed such that the propagation angle is different between adjacent resonators, elastic waves that leak from the resonators are dispersed. As a result, it is possible to reduce a situation in which one resonator deteriorates the spurious characteristic of the other resonator. The adjacent resonators herein mean that no resonator is located between the resonators, and the direction in which the resonators are adjacent to each other is not limited. However, when the propagation angle is different between resonators located on an extension line of the propagation direction, the above-described effect is enhanced.

In FIG. 5, each resonator 15 is illustrated in a rectangular shape, and the long side corresponds to the propagation direction. For reference, in FIG. 5, the propagation direction in each resonator, that is, the repetitive arrangement direction of electrode fingers, is indicated by an arrow in the rectangle representing the resonator in some cases.

The characteristic that there is no change in characteristic such as Maxphase, Δf, or spurious even when the propagation angle is changed as described above appears only when the LN layer 7 is used and the thickness thereof is 0.3λ or less. Results of verifying the influence of the propagation angle when the above-described condition is not satisfied will be described below.

As Comparative Example 1, a resonator was fabricated which had a configuration equivalent to that of the above-described embodiment except that a thick LN substrate was used as the LN layer 7 and the multilayer film 5 was not provided, and the characteristics thereof were measured with the propagation angle being varied.

As Comparative Example 2, a resonator was fabricated which included an LN substrate whose Euler angles were (0, 38, ψ) different from those in Comparative Example and the characteristics thereof were measured with the propagation angle being varied. The Euler angles correspond to cut angles typically used for an LN substrate.

Furthermore, as Comparative Example 1-2, a resonator was fabricated which included the LN substrate of Comparative Example 1 whose thickness was 0.5λ and which included a Si substrate disposed on a lower surface of the LN substrate, and the characteristics thereof were measured with the propagation angle being varied.

Similarly, as Comparative Example 2-2, a resonator was fabricated which included the LN substrate of Comparative Example 2 whose thickness was 0.5λ and which included a Si substrate disposed on a lower surface of the LN substrate, and the characteristics thereof were measured with the propagation angle being varied.

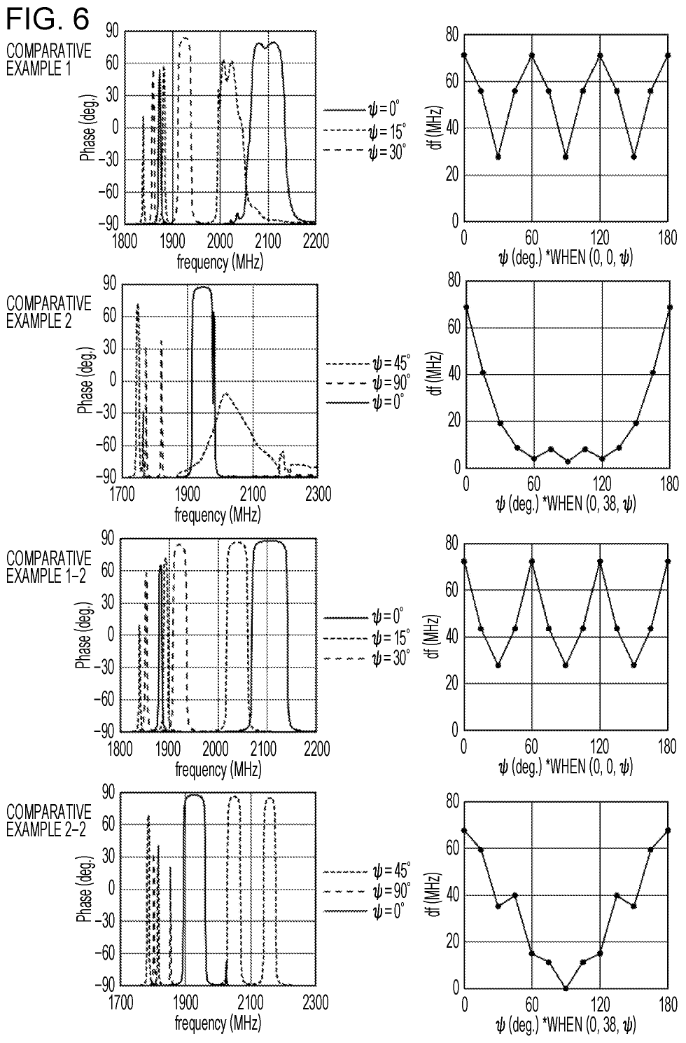

FIG. 6 illustrates, using graphs, correlations between the phase characteristic and the propagation angle, and correlations between Δf and the propagation angle, of Comparative Examples 1, 1-2, 2, and 2-1. In every case, a slab-mode elastic wave was not observed, and it was confirmed that the resonant frequency was on the order of 2 MHz. That is, it was confirmed that the type of elastic wave to be handled was different from that in the above-described embodiment.

Furthermore, in every case, it can be confirmed that a propagation angle other than 0° is not usable because a change in propagation angle causes spurious, a decrease in Δf, or deterioration in MaxPhase. A case where LT was used as the piezoelectric layer was also confirmed, but a change in characteristics caused by the propagation angle was remarkable.

(Thickness of LN Layer)

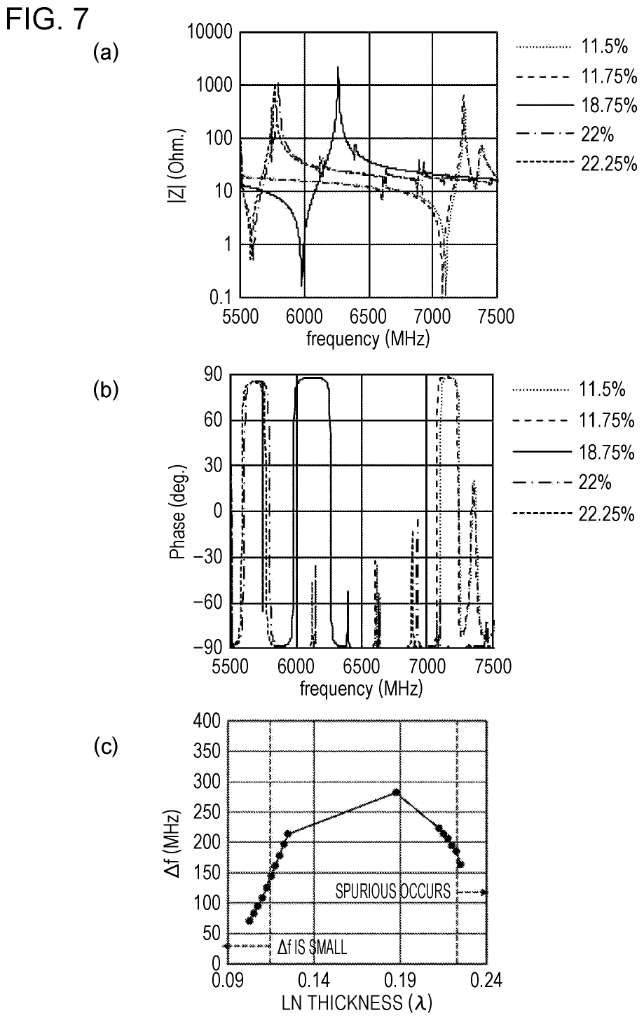

Next, the characteristics of the elastic wave element were measured with the thickness of the LN layer 7 being variously changed. Specifically, FIG. 7(a) illustrates impedance characteristics, FIG. 7(b) illustrates phase characteristics, and FIG. 7(c) illustrates the value of Δf, when the LN layer 7 had a thickness that varied from 0.115λ to 0.2225λ. FIG. 7 includes graphs corresponding to those in FIG. 3 in a case where the thickness of the LN layer was varied.

As is apparent from FIG. 7, when the thickness is less than 0.1175λ, Δf is small and it is not necessary to use LN. When the thickness is more than 0.22λ, spurious occurs. From the above, the thickness of the LN layer 7 may be 0.1175λ or more and 0.22λ or less. The characteristics illustrated in FIG. 3 were obtained when the thickness of the LN layer 7 was 0.1875λ.

(Materials of Multilayer Film)

Next, as a result of conducting a simulation while variously changing the material of the multilayer film 5, it was found that use of SiO₂ and Ta₂O₅ as materials of the multilayer film 5 made it possible to achieve resonance in a relatively high frequency region by using a slab-mode elastic wave.

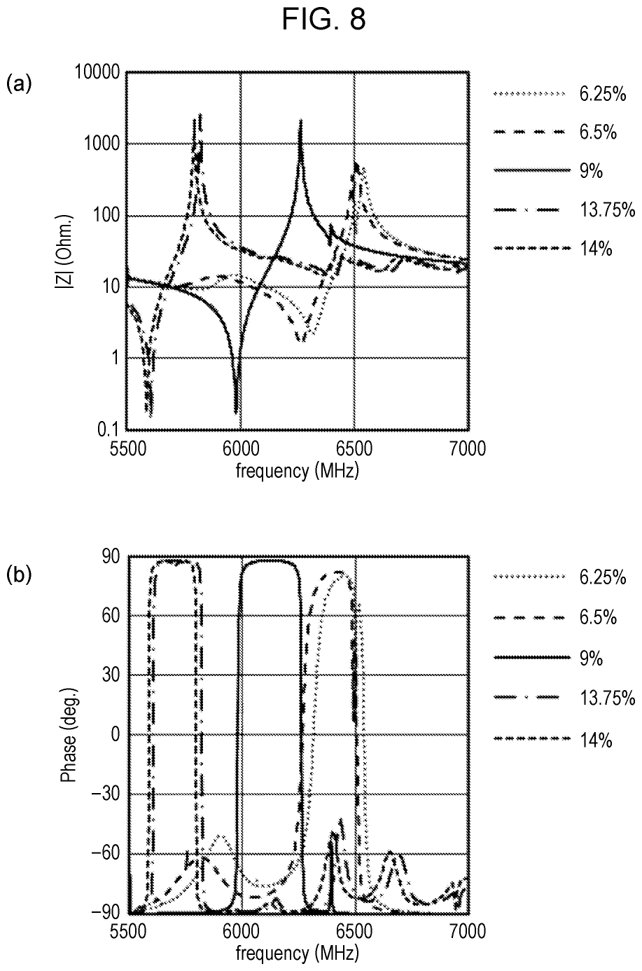

FIG. 8(a) and FIG. 8(b) illustrate a result of a simulation in which the thickness of the low acoustic velocity layer 11 was changed with the thickness of the high acoustic velocity layer 13 being 0.07λ. FIG. 8(a) illustrates impedance characteristics, and FIG. 8(b) illustrates phase characteristics. In these graphs, the horizontal axis represents frequency, and the vertical axis represents the absolute value of impedance in FIG. 8(a) and phase in FIG. 8(b).

As is apparent from FIG. 8, when the thickness of the low acoustic velocity layer 11 is less than 6.5% of the wavelength λ, close-in spurious occurs, and the phase characteristic near fr degrades. When the thickness is more than 13.75% of the wavelength λ, spurious occurs between fr and fa. From the above, the thickness of the low acoustic velocity layer 11 may be 0.065λ or more and 0.1375λ or less.

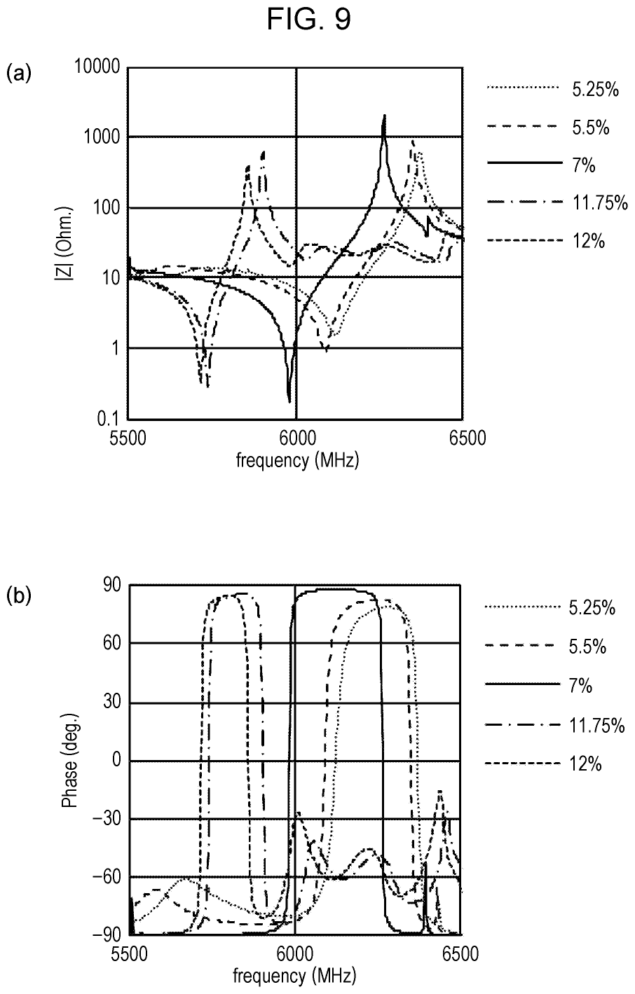

Similarly, FIG. 9(a) and FIG. 9(b) illustrate a result of a simulation in which the thickness of the high acoustic velocity layer 13 was changed with the thickness of the low acoustic velocity layer 11 being 0.09λ. FIG. 9(a) and FIG. 9(b) are graphs corresponding to FIG. 8(a) and FIG. 8(b).

As is apparent from FIG. 9, when the thickness of the high acoustic velocity layer 13 is less than 5.5% of the wavelength λ, close-in spurious occurs, and the phase characteristic near fr degrades. On the other hand, when the thickness is more than 11.75% of the wavelength λ, Δf decreases. From the above, the thickness of the high acoustic velocity layer 13 may be 0.055λ or more and 0.1175λ or less.

The surface roughness of each layer constituting the multilayer film 5 may be increased from the LN layer 7 side toward the substrate 3. More specifically, among the low acoustic velocity layers 11, the layer that is in contact with the LN layer 7 has a smaller surface roughness than the layer located closest to the substrate 3. With this configuration, a bulk wave transmitted from the LN layer 3 can be scattered.

(Thickness of Conductive Layer 9)

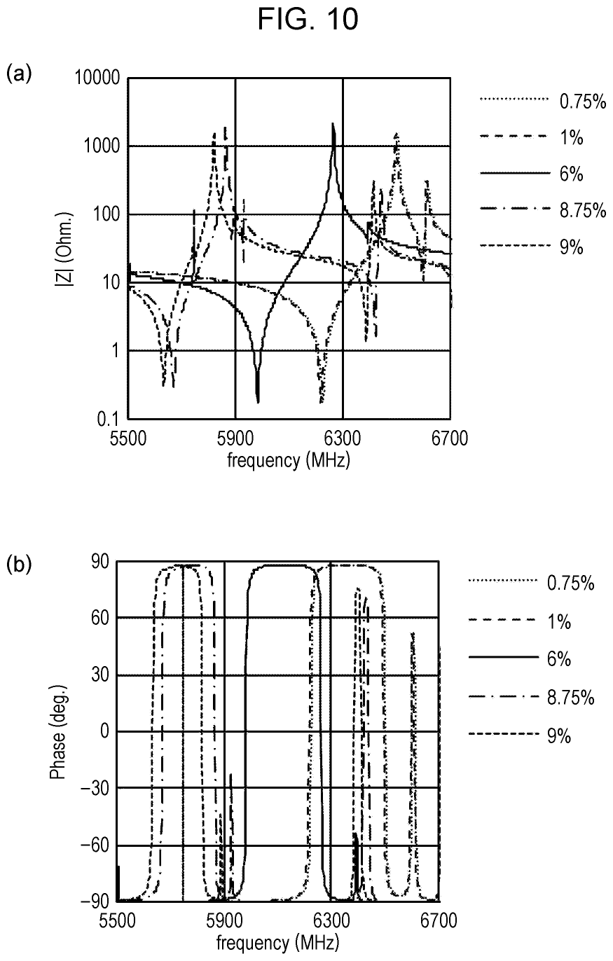

Next, the impedance characteristics and the phase characteristics of the elastic wave element with varied thickness of the conductive layer 9 were simulated. The results are illustrated in FIG. 10. FIG. 10(a) and FIG. 10(b) are graphs corresponding to FIG. 9(a) and FIG. 9(b). As is apparent from FIG. 10, it was found that spurious occurred when the thickness of the conductive layer 9 was more than 0.875λ. Although it was not confirmed in the simulation, when the thickness of the conductive layer is less than 0.01λ, there is a possibility that an electrode resistance actually increases and the characteristics deteriorate. Thus, the thickness of the conductive layer 9 may be 0.01λ or more and 0.0875λ or less.

(Method of Manufacturing Elastic Wave Device)

The elastic wave device 1 may be manufactured by using various known processes in combination. For example, the low acoustic velocity layers 11 and the high acoustic velocity layers 13 are sequentially formed on a wafer that is to serve as the substrate 3, by using a thin film formation method such as chemical vapor deposition (CVD). On the other hand, a wafer that is to serve as the LN layer 7 is prepared by a fabrication process similar to that of a wafer of a typical LN substrate. Subsequently, the wafer that is to serve as the LN layer 7 is bonded to the wafer that is to serve as the substrate 3 and the multilayer film 5. In the bonding, the LN layer 7 is directly brought into contact with the uppermost layer (for example, a SiO₂ layer) of the multilayer film 5. Heat treatment or the like may be performed before or after the bringing into contact. Thereafter, a metal layer that is to serve as the conductive layer 9 is formed and patterned on the upper surface of the wafer that is to serve as the LN layer 7, and the wafer is diced. Accordingly, the elastic wave device 1 is fabricated. An appropriate process may of course be added according to the form of the package or the like.

(Modification of Elastic Wave Device)

In the example described above, a description has been given of the configuration in which a slab-mode elastic wave (Lamb wave) is confined in the LN layer 7 by using the multilayer film 5, but the configuration is not limited thereto.

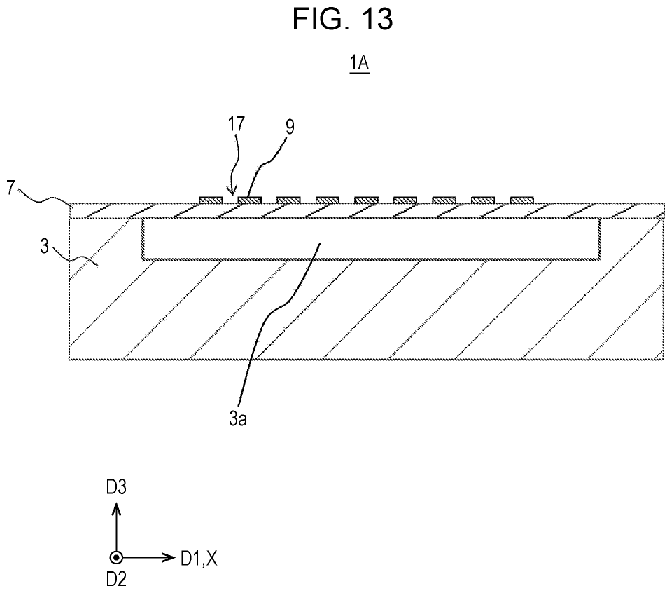

For example, as illustrated in FIG. 13, an elastic wave device 1A without a multilayer film may be used. The elastic wave device 1A is similar to the elastic wave device 1 in that the LN layer 7 is supported by the substrate 3. However, the elastic wave device 1A does not include the multilayer film 5 and has a membrane shape in which a cavity is located between the substrate 3 and a region of the LN layer 7 where the IDT electrode 19 is located. This cavity enables an elastic wave to be confined in the LN layer 7.

Hereinafter, only differences from the elastic wave device 1 will be described.

In FIG. 13, the upper surface of the substrate 3 has a recessed portion 3a. The IN layer 7 is directly or indirectly bonded onto the substrate 3 such that the recessed portion 3a and the IDT electrode 19 overlap each other in top view.

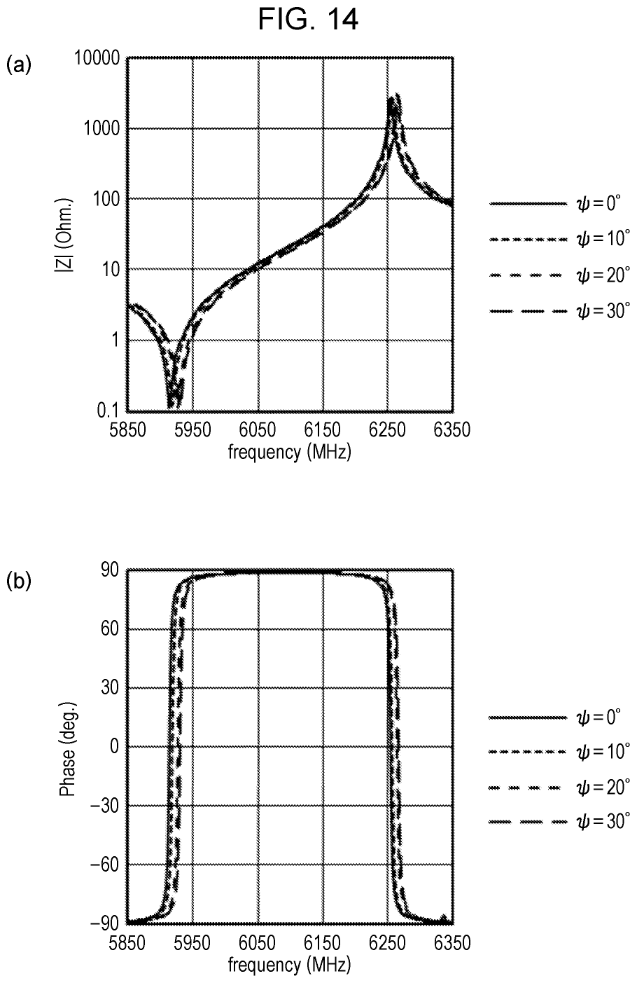

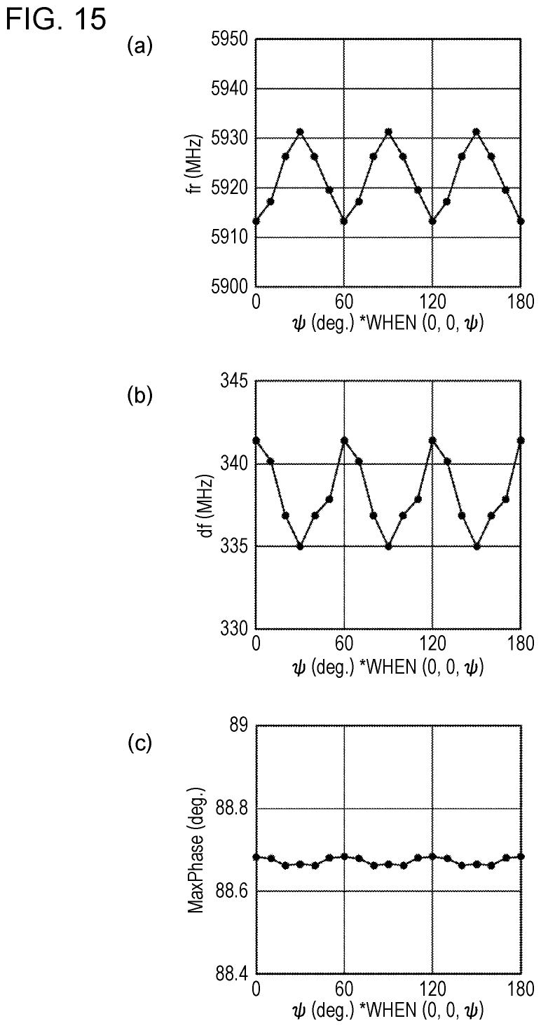

FIG. 14 and FIG. 15 illustrate graphs for the elastic wave device 1A corresponding to FIG. 4. The elastic wave device 1A has a basic configuration in which the Euler angles of the LN layer 7 are (0, 0, ψ), the thickness of the LN layer 7 is 0.185λ, the thickness of the conductive layer 9 is 0.065λ, the pitch p is 1 μm and the duty is 0.5.

FIG. 14(a) and FIG. 14(b) illustrate impedance characteristics and phase characteristics when ψ was changed. FIG. 15(a), FIG. 15(b), and FIG. 15(c) illustrate fr, Δf, and the maximum phase value when ψ was changed. As is apparent from FIG. 14 and FIG. 15, it was confirmed that, in the elastic wave device 1A, as in the elastic wave device 1, variation in fr, Δf, and the maximum phase value was small even when ψ (propagation angle) was changed.

In the example illustrated in FIG. 13, the substrate 3 has a recessed portion, but the configuration is not limited thereto. For example, a protruding portion that functions as a spacer may be provided on the upper surface of the substrate 3 having a flat upper surface, and an LN layer may be disposed on the protruding portion. The protruding portion may be made of a material different from that of the substrate 3.

In addition, in FIG. 13, a single recessed portion 3a may be provided for a single resonator, or a recessed portion 3a for a plurality of resonators may be provided. The material of the substrate 3 is not particularly limited, but a Si substrate may be used in consideration of ease of processing.

(Application Example of Elastic Wave Device: Splitter)

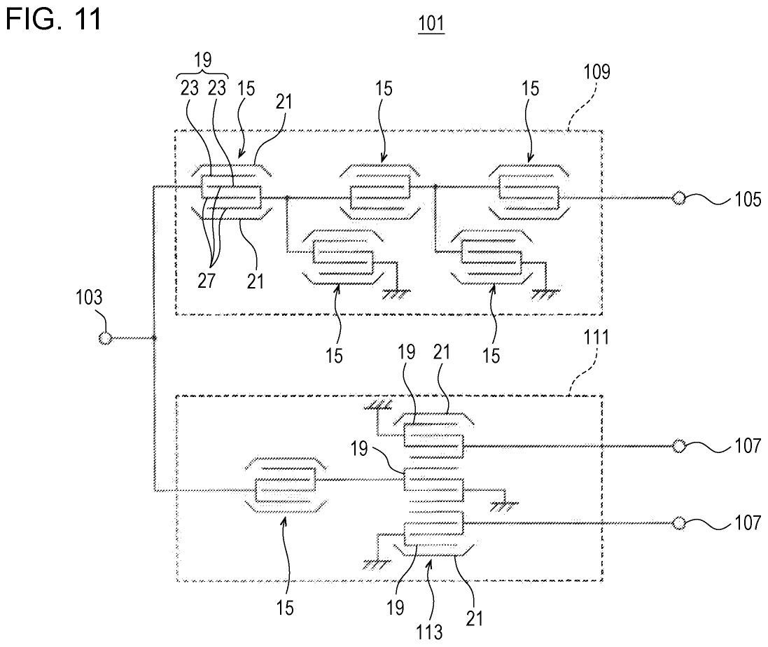

FIG. 11 is a circuit diagram schematically illustrating a configuration of a splitter 101 as an application example of the elastic wave device 1. As is understood from the reference signs illustrated on the upper left side of this figure on paper, in this figure, each comb-teeth electrode 23 is schematically represented by a bifurcated fork shape, and each reflector 21 is represented by one line that is bent at both ends.

The splitter 101 includes, for example, a transmission filter 109 that filters a transmission signal from a transmission terminal 105 and outputs the filtered transmission signal to an antenna terminal 103, and a reception filter 111 that filters a reception signal from the antenna terminal 103 and outputs the filtered reception signal to a pair of reception terminals 107.

The transmission filter 109 is formed of, for example, a ladder filter in which a plurality of resonators 15 are connected to each other in a ladder shape. That is, the transmission filter 109 includes one or more resonators 15 connected in series between the transmission terminal 105 and the antenna terminal 103, and one or more resonators 15 (parallel arm) connecting the series line (series arm) of the resonators 15 to a reference potential. The plurality of resonators 15 constituting the transmission filter 109 are provided, for example, on or in the same affixed substrate 2 (3, 5, and 7).

The reception filter 111 includes, for example, the resonator 15 and a multi-mode filter (including a double-mode filter) 113. The multi-mode filter 113 includes a plurality of (three in the illustrated example) IDT electrodes 19 arranged in the elastic wave propagation direction and a pair of reflectors 21 disposed on both sides thereof. The resonator 15 and the multi-mode filter 113 that constitute the reception filter 111 are provided, for example, on or in the same affixed substrate 2.

The transmission filter 109 and the reception filter 111 may be provided on or in the same affixed substrate 2, or may be provided on or in different affixed substrates 2. FIG. 11 illustrates merely an example of the configuration of the splitter 101. For example, the reception filter 111 may be formed of a ladder filter similarly to the transmission filter 109.

Although a description has been given of the case where the splitter 101 includes the transmission filter 109 and the reception filter 111, the splitter 101 is not limited thereto. For example, the splitter 101 may be a diplexer or a multiplexer including three or more filters.

(Application Example of Elastic Wave Device: Communication Apparatus)

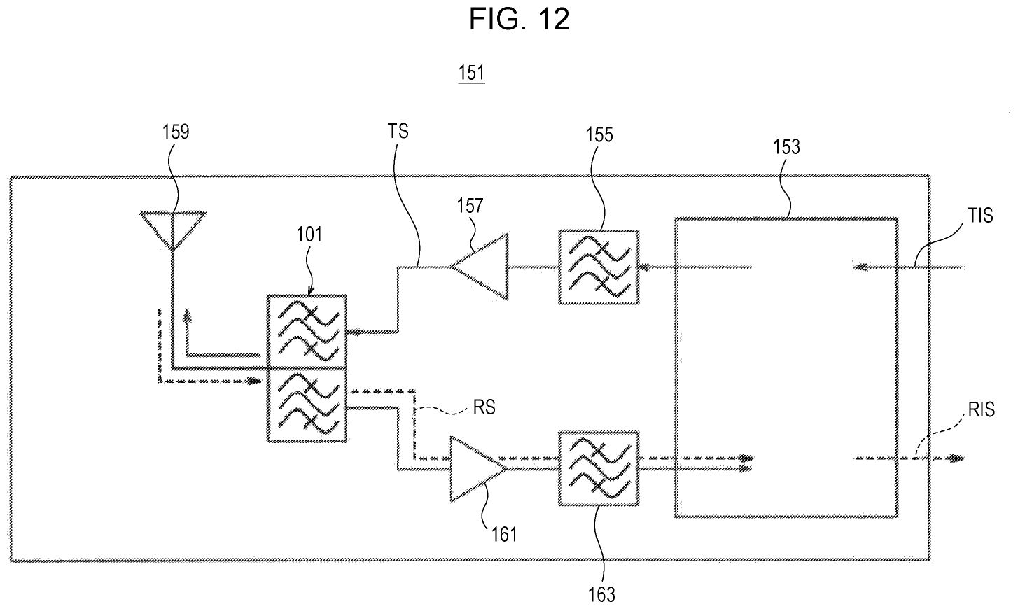

FIG. 12 is a block diagram illustrating a main part of a communication apparatus 151 as an application example of the elastic wave device 1 (splitter 101). The communication apparatus 151 performs wireless communication using a radio wave, and includes the splitter 101.

In the communication apparatus 151, a transmission information signal TIS including information to be transmitted is subjected to modulation and frequency up-conversion (conversion of a carrier frequency to a radio frequency signal) performed by a radio frequency integrated circuit (RF-IC) 153, thereby being converted to a transmission signal TS. The transmission signal TS is subjected to removal of unnecessary components outside a transmission pass band, performed by a band-pass filter 155, is amplified by an amplifier 157, and is input to the splitter 101 (the transmission terminal 105). Subsequently, the splitter 101 (the transmission filter 109) removes unnecessary components outside the transmission pass band from the transmission signal TS input thereto, and outputs the transmission signal TS after the removal from the antenna terminal 103 to an antenna 159. The antenna 159 converts the electric signal (transmission signal TS) input thereto into a radio signal (radio wave) and transmits the radio signal.

In the communication apparatus 151, a radio signal (radio wave) received by the antenna 159 is converted into an electric signal (reception signal RS) by the antenna 159 and is input to the splitter 101 (the antenna terminal 103). The splitter 101 (the reception filter 111) removes unnecessary components outside a reception pass band from the reception signal RS input thereto and outputs a resultant signal from the reception terminals 107 to an amplifier 161. The output reception signal RS is amplified by the amplifier 161, and is subjected to removal of unnecessary components outside the reception pass band, performed by a band-pass filter 163. Subsequently, the reception signal RS is subjected to frequency down-conversion and demodulation performed by the RF-IC 153, thereby being converted into a reception information signal RIS.

The transmission information signal TIS and the reception information signal RIS may be low-frequency signals (baseband signals) including appropriate information and are, for example, analog audio signals or digitized audio signals. The pass band of a radio signal may be appropriately set and may be, in the present embodiment, a pass band of a relatively high frequency (for example, 5 GHz or more). The modulation scheme may be any one of phase modulation, amplitude modulation, and frequency modulation, or may be a combination of any two or more of them. A direct conversion scheme is illustrated as a circuit scheme in FIG. 12. However, any other appropriate scheme, for example, a double superheterodyne scheme, may be used. FIG. 12 schematically illustrates only a main part. A low-pass filter, an isolator, or the like may be added at an appropriate position. In addition, the position of the amplifier or the like may be changed.

The present invention is not limited to the above embodiment and may be implemented in various forms. For example, the thickness of each layer and the Euler angles of the LN layer may have values outside the ranges exemplified in the embodiment.

### REFERENCE SIGNS LIST

1 . . . elastic wave device, 3 . . . substrate, 5 . . . multilayer film, 7 . . . LN Layer, 19 . . . IDT electrode, 11 . . . SiO₂ Layer, 13 . . . Ta₂O₅ layer

1. An elastic wave device comprising:
an LN layer made of a single crystal of LiNbO₃; and
a plurality of resonators each including an IDT electrode located on the LN layer,
wherein the LN layer has a thickness of 0.3λ or less, where λ is twice a pitch of electrode fingers of the IDT electrode, and
wherein the LN layer has Euler angles (ϕ, θ, ψ) of (0°±10°, −25° or more and 15° or less, 0° or more and 360°).

2. The elastic wave device according to claim 1,
wherein the plurality of resonators include a first resonator and a second resonator, and
wherein the first resonator is different from the second resonator in propagation angle.

3. The elastic wave device according to claim 2,
wherein the plurality of resonators constitute a ladder filter,
wherein the first resonator serves as a series resonator and the second resonator serves as a parallel resonator, and
wherein when n1 and n2 are each a natural number of 0 to 5, the first resonator has a propagation angle of 20°+60°×n1 or more and 40°+60°×n1 or less, and the second resonator has a propagation angle of −10°+60°×n2 or more and 10°+60°×n2 or less.

4. The elastic wave device according to claim 2, wherein no resonator is present between the first resonator and the second resonator.

5. The elastic wave device according to claim 1, comprising:
a substrate; and
a multilayer film located on the substrate,
wherein the IDT electrode is located on the multilayer film.

6. The elastic wave device according to claim 4, wherein the multilayer film includes a low acoustic velocity layer and a high acoustic velocity layer, the low acoustic velocity layer being made of SiO₂, the high acoustic velocity layer being made of Ta₂O₅.

7. The elastic wave device according to claim 6,
wherein the LN layer has a thickness of 0.1175λ or more and 0.22λ or less,
wherein the low acoustic velocity layer has a thickness of 0.065λ or more and 0.1375λ or less, and
wherein the high acoustic velocity layer has a thickness of 0.055λ or more and 0.117λ or less.

8. The elastic wave device according to claim 1, wherein the multilayer film includes a first layer and a second layer that is located closer than the first layer to the substrate, the first layer having a smaller surface roughness than the second layer.

9. The elastic wave device according to claim 1, comprising
a substrate that supports the LN layer,
wherein a cavity is present between the substrate and a region of the LN layer where the plurality of resonators are located.

10. A splitter comprising:
an antenna terminal;
a transmission filter configured to filter a signal that is to be output to the antenna terminal; and
a reception filter configured to filter a signal received from the antenna terminal,
wherein at least one of the transmission filter or the reception filter includes the elastic wave device according to claim 1.

11. A communication apparatus comprising:
an antenna;
the splitter according to claim 10, comprising the antenna terminal connected to the antenna; and
an IC connected to the transmission filter and the reception filter, the IC being connected on an opposite side from the antenna terminal in a signal path.
